(19) United States
(12) Patent Application Publication
(10) Pub. No.: US 2010/0072552 A1
(43) Pub. Date: Mar. 25, 2010

(54) FIELD EFFECT TRANSISTOR FOR PREVENTING COLLAPSE OR DEFORMATION OF ACTIVE REGIONS

(75) Inventors: Hideo SUNAMI, Higashi-Hiroshima-shi (JP); Atsushi Sugimura, Higashi-Hiroshima-shi (JP); Kiyoshi Okuyama, Higashi-Hiroshima-shi (JP); Kiyonori Oyu, Chuo-ku (JP); Hideharu Miyake, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory,Inc, Tokyo (JP)

(21) Appl. No.: 12/561,793

(22) Filed: Sep. 17, 2009

(30) Foreign Application Priority Data
Sep. 18, 2008 (JP) 2008-239494

(51) Int. Cl. H01L 27/105; H01L 29/78; H01L 21/336

(52) U.S. Cl. 257/365; 438/283; 257/368; 257/E21.421; 257/E27.081; 257/E29.264

(57) ABSTRACT

A field effect transistor includes an active region provided in a projecting part on a surface of a semiconductor substrate, the projecting part extending in a fixed direction parallel to the surface, and a gate electrode provided on a sidewall of the projecting part along the fixed direction with a gate insulating films interposed.

This application is based upon and claims the benefit of priority from Japanese Patent Application No. 2008-239494 filed on Sep. 18, 2008, the content of which is incorporated by reference.

### BACKGROUND OF THE INVENTION

1. Field of the Invention

The present invention relates to a field effect transistor, a memory cell, and a fabrication method of a field effect transistor.

2. Description of the Related Art

Nearly all monolithic semiconductor integrated circuits since 1970 have been made from MOS (Metal-Oxide film-Semiconductor) FETs (Field effect Transistors) that use silicon substrates. Integrated circuits that use these transistors have been formed in a planar shape on the surface of a single-crystal silicon substrate. This type of transistor is referred to hereinbelow as a planar transistor.

Although the performance of an integrated circuit is determined by a number of factors, performance basically depends on the performance of transistors. Because the performance of an integrated circuit increases as the transistors it uses become smaller, the gate length (which is substantially equivalent to the channel length) that is of key importance in transistors, was approximately 10 μm in 1970, approximately 1 μm in 1985, and approximately 0.1 μm (=100 nm) in 2000, and thus has been downsized to 1/10 every fifteen years. This downsizing trend is still in progress, but a gate length in the range of 5-10 nm is estimated to be the limit in order for a planar MOSFET to operate normally as expected.

The miniaturization of transistors has been accompanied by greater performance problems. The greatest of these problems is known as the “short channel effect” and this problem causes phenomena such as the increase of the cut-off current of the transistor that essentially prevents cut-off, and, because gate voltage for cut-off (i.e., the threshold voltage) is strongly dependent on the gate length, dimensional variations in fabrication strongly and directly affect transistor performance.

On the other hand, in dynamic random access memory (hereinbelow abbreviated as “DRAM”) that uses these transistors as cell transistors, increase of the cut-off current of miniaturized transistors causes loss of information (in the case of DRAM, charge) that has been stored, and cut-off current is therefore preferably made as low as possible. In large-capacity DRAM, the area of memory cells must be reduced in order to cut costs, and the downsizing of a memory cell and the stored information-holding characteristic are therefore reciprocal characteristics and constitute the greatest factor that prevents the realization of DRAM of even greater large scale.

In a planar transistor, parts such as the drain electrode, the source electrode, the active region through which current flows from the drain electrode to the source electrode, an element-isolation region, and connection holes to each of the source electrode and drain electrode are formed in a plane. As a result, the entire area for arranging these electrodes and regions increases in size, and the planar transistor is structure that cannot be used for constructing micro-transistors.

Based on these points, vertical field effect transistors are being investigated as a substitute for planar transistors. One example of a vertical field effect transistor is disclosed in JP-A-2008-66721 (hereinbelow referred to as Patent Document 1). In the vertical field effect transistor construction that projects in pillar form as disclosed in Patent Document 1, extremely thin silicon pillars are formed in the fabrication process and the problem therefore arises that the construction is difficult to handle. For example, the substrate is dipped in an aqueous hydrofluoric solution to carry out processes such as cleaning the silicon wafer, but the surface tension in some cases causes collapse or deformation of the thin silicon pillars.

### SUMMARY

In one embodiment, there is provided a field effect transistor that includes an active region provided on a projecting part on a surface of a semiconductor substrate, the projecting part extending in a fixed direction parallel to the surface, and a gate electrode that is provided on a sidewall of the projecting part along the fixed direction with a gate insulating film interposed.

### BRIEF DESCRIPTION OF THE DRAWINGS

The above features and advantages of the present invention will be more apparent from the following description of certain preferred embodiments taken in conjunction with the accompanying drawings, in which:

FIG. 1 is an outer perspective view showing an example of the configuration of the field effect transistor of a first embodiment;

FIGS. 2 to 7 are outer perspective views for explaining the method of fabricating the field effect transistor of the first embodiment;

FIG. 8 is a photograph taken from directly above the construction shown in FIG. 7 by a scanning electron microscope;

FIG. 9 is a graph showing the results of measuring the characteristics of the drain current and gate voltage of the field effect transistor of the first embodiment;

FIG. 10 is an outer perspective view showing an example of the configuration of the field effect transistor of a second embodiment;

FIGS. 11 to 22 are outer perspective views for explaining the method of fabricating the field effect transistor of the second embodiment;

FIGS. 23 to 25 are outer perspective views for explaining the method of fabricating the field effect transistor of a third embodiment;

FIG. 26 is an outer perspective view showing an example of the configuration of the field effect transistor of a fourth embodiment;

FIG. 27 is a block diagram showing an example of the configuration of a semiconductor memory device;

FIG. 28A shows an example of a circuit in which the field effect transistor of the present invention is used in a cell transistor of a memory cell; and

FIG. 28B shows an example of a circuit in which the field effect transistor of the present invention is used in a cell transistor of a memory cell.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

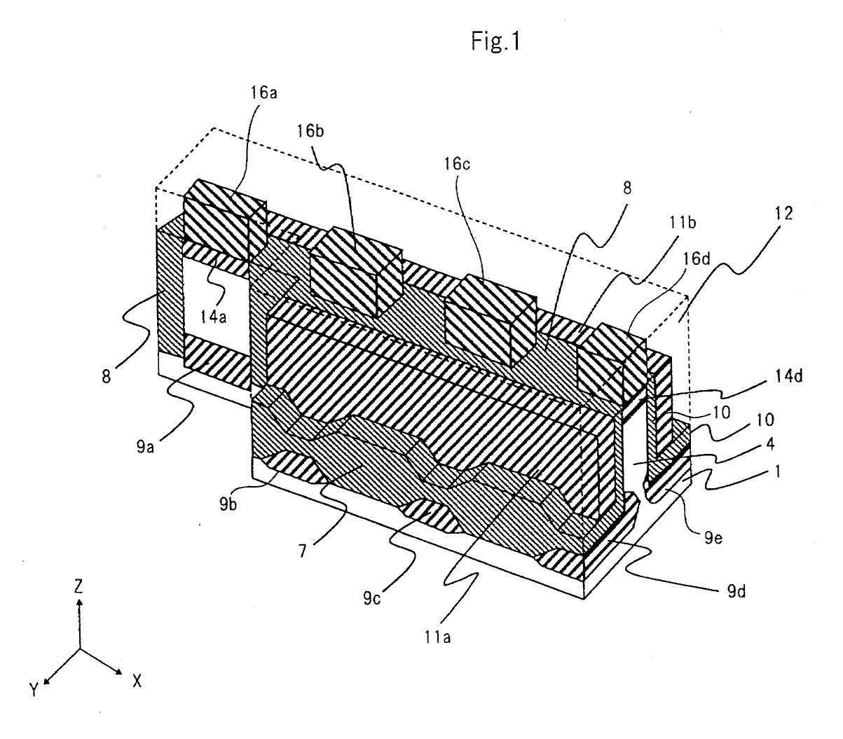

First, regarding the configuration of the present embodiment, FIG. 1 is an outer perspective view showing an example of the configuration of the field effect transistor of the present embodiment. To explain the directions in the three-dimensional structure, the X-axis, Y-axis, and Z-axis shown in FIG. 1 are defined.

The construction shown in FIG. 1 is a construction formed close to the surface of silicon substrate 1 that constitutes the semiconductor substrate and that is realized by cutting away from silicon substrate 1. In the present embodiment, a projecting part is provided on the surface of silicon substrate 1, and this projecting part extends in a fixed direction that is parallel to the main surface. FIG. 1 shows a case in which the projecting part extends in the X-axis direction. If the substrate is assumed to be the foundation of the construction, the projecting part resembles a beam that is provided parallel to the foundation, and the projecting part is therefore referred to as a “silicon beam” hereinbelow and is indicated by reference number 4 in the figures.

Silicon beam 4 is provided with: pillar-shaped active region (not shown) that includes points in which a channel is generated during operation of the FET, and beam field oxide film 8 for isolating FETs that are adjacent in the X-axis direction. Although not shown in FIG. 1, the semiconductor portion of silicon beam 4 is separated by beam field oxide film 8 into four pillar-shaped active regions.

Pillar-shaped active regions are provided corresponding to the positions of each of electrodes 16a-16d. In FIG. 1, the profile of the pillar-shaped active region that is connected to electrode 16a is shown in the profile obtained by cutting from electrode 16a to silicon substrate 1 by a plane that contains the Z-axis and X-axis. In addition, the profile of the pillar-shaped active region that is connected to electrode 16d is shown in the profile obtained by cutting from electrode 16d to silicon substrate 1 by a plane that contains the Z-axis and Y-axis.

Regarding the FET of the present embodiment, an example is described in which two FETs are provided corresponding to the pillar-shaped active region that is connected to electrode 16d.

As shown in FIG. 1, upper diffusion layer 14d is provided on the upper portion of the pillar-shaped active region that is a portion of silicon beam 4, and a pair of lower diffusion layers 9d and 9e are provided near the surface of silicon substrate 1 at the lower portion of the pillar-shaped active region. The pillar-shaped active region is connected to electrode 16d by way of upper diffusion layer 14d.

One of the two FETs includes: a pillar-shaped active region in which a channel is generated during operation, upper diffusion layer 14d that corresponds to the drain electrode, lower diffusion layer 9d that corresponds to the source electrode, and gate electrode 11a that is provided on one of the side-walls of the pillar-shaped active region with gate oxide film 10 interposed. The other FET includes: the above-described pillar-shaped active region, upper diffusion layer 14d that corresponds to the drain electrode, lower diffusion layer 9e that corresponds to the source electrode, and gate electrode 11b provided on the other side-wall of the pillar-shaped active region with gate oxide film 10 interposed. Gate electrodes 11a and 11b extend in the same direction as the longitudinal direction of silicon beam 4 and are provided opposite each other to sandwich silicon beam 4 on which gate oxide film 10 is provided on both side surfaces. These two FETs share the pillar-shaped active region and drain electrode. Thus, in the construction shown in FIG. 1, two FETs are formed for a single pillar-shaped active region.

A simple explanation of the operation of the FETs of the present embodiment is next presented for one of the above-described FETs. When a voltage of at least the threshold value voltage is applied to gate electrode 11a while a predetermined voltage is applied to upper diffusion layer 14d of the drain electrode, a channel current flows in the Z-axis direction in the side surface of the pillar-shaped active region and the FET turns ON. If the application of voltage to gate electrode 11a is halted, the FET turns OFF.

In the construction shown in FIG. 1, two FETs are provided corresponding to each of electrodes 16a-16d for a total of eight FETs provided. If the voltage applied to gate electrode 11a or gate electrode 11b is controlled while a predetermined voltage is applied to electrodes 16a-16d, the ON/OFF of the four FETs can be switched at the same timing. If the voltage that is applied to each of gate electrode 11a and gate electrode 11b is controlled at the same time, the ON/OFF of the eight FETs can be switched at the same timing.

Still further, one FET of the eight FETs can be caused to operate if any of gate electrodes 11a and 11b and any of electrodes 16a-16d are selected.

The construction shown in FIG. 1 is a construction in which the active regions of the field effect transistors are isolated by an oxide film provided locally on silicon beam 4 that extends in a fixed direction, whereby the field effect transistors of the present embodiment are referred to as “Local Oxide Isolated Field effect Transistors,” this term being abbreviated as LOIFET. This feature is shared with the other embodiments to be described hereinbelow.

FIG. 1 shows a construction in which four pillar-shaped active regions are provided with two FETs provided for each pillar-shaped active region, but the number of the pillar-shaped active regions is not limited to four and can also be one, and further, the number of FETs provided corresponding to a single pillar-shaped active region may be one.

In addition, although an example was described in which the upper diffusion layer was the drain electrode and a lower diffusion layer was the source electrode, the upper diffusion layer may be the source electrode, and a lower diffusion layer may be the drain electrode. The electrodes of the upper diffusion layer and the lower diffusion layers may be set according to the direction of current flow.

Although explanation has been given regarding electrodes 16a-16d, gate electrodes 11a and 11b, upper diffusion layers 14a and 14d and lower diffusion layers 9a-9e shown in FIG. 1 by adding alphabet letters to the reference numbers to distinguish the plurality of positions of the same types of components, the alphabet letters are omitted in the following explanation when there is no need to distinguish the components. Still further, although explanation regarded a case in which gate oxide film 10 was used as the gate insulator, the material of the gate insulator is not limited to a silicon oxide film.

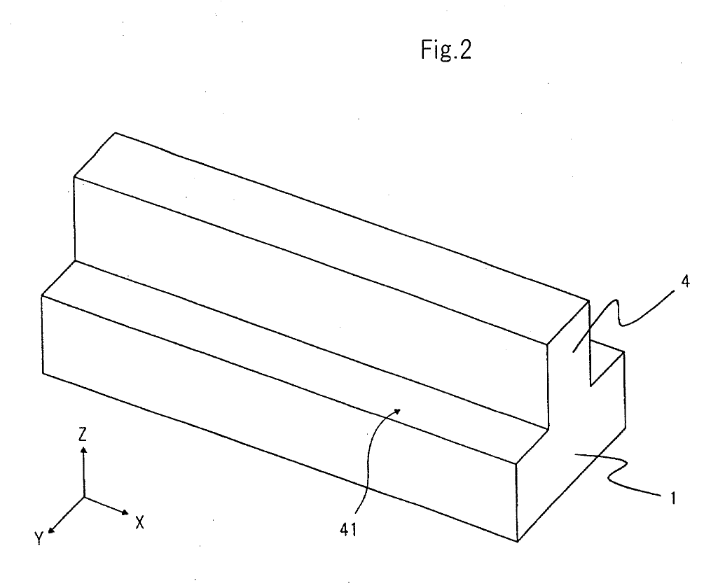

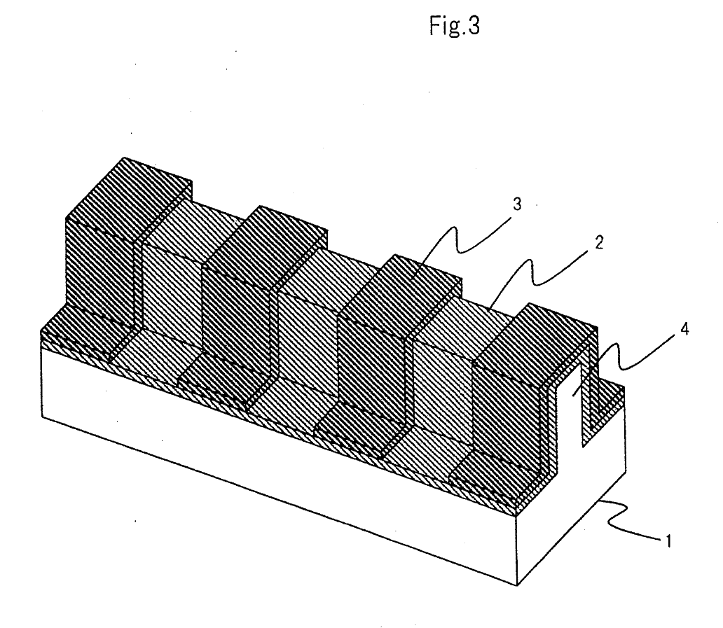

The fabrication method of the field effect transistor shown in FIG. 1 will next be explained. FIGS. 1 to 7 are outer perspective views for explaining the fabrication method of the field effect transistor of the present embodiment. FIG. 2 shows the three axes that correspond to the X-axis, Y-axis, and Z-axis shown in FIG. 1. Although the indication of these axes has been omitted from FIG. 3 and following figures as well, the longitudinal direction of silicon beam 4 is assumed to be the X-axis direction, the direction perpendicular to the principal surface of silicon substrate 1 is assumed to be the Z-axis direction, and the direction that is orthogonal to each of the X-axis and Z-axis is assumed to be the Y-axis direction.

Silicon substrate 1 is prepared in which the conductive impurity is p-type, the surface orientation of the principal surface is the (100) plane, and the specific resistance is 10 Ω-cm. Silicon substrate 1 is subjected to a pattern formation process by means of a photo-etching method (photolithography method) to form silicon beam 4 having a width of 200 nm and a height of 400 nm above the principal surface of semiconductor substrate 1, as shown in FIG. 2. Regarding silicon beam 4, the height is the length in the Z-axis direction that is perpendicular to the principal surface of silicon substrate 1, the width is the thickness in the Y-axis direction, and the longitudinal direction is the X-axis direction. Surface 41 shown in FIG. 2 is the principal surface of the substrate. Photolithography steps and dry etching steps that are frequently carried out in the fabrication process of semiconductor devices are used not only in the processes described in FIG. 2 but in all of the pattern formation processes described hereinbelow, and a detailed explanation of the pattern formation process in each figure is therefore omitted.

Using a substrate in which the surface orientation is the (110) plane for silicon substrate 1 and etching the substrate surface by an aqueous TMAH (tetra-methyl-ammonium-hydroxide) solution or an aqueous KOH solution for which the etching speed on the (111) plane is extremely slow compared to other surfaces has the advantage of obtaining vertical side-walls that are smooth on the atomic level, but on the other hand, suffers from the disadvantage that the surface orientation of the crystal surface of the side-walls is (111) and the mobility of the carrier of the fabricated transistor is lower than for the other surfaces. The advantage of smoothing during processing and the disadvantage of the drop in carrier mobility resulting from the dependency on surface orientation offset each other, and the plane that the device designer selects as the principal surface therefore depends on the performance and specifications that are required of the integrated circuit that is the object of fabrication.

Next, as shown in FIG. 3, using a dry oxidation method to carry out oxidation at 1000° C. for ten minutes, pad oxide film 2 having a thickness of 10 nm is formed over the entire surface of silicon substrate 1 that includes silicon beam 4. Next, silicon nitride film (Si₃N₄) 3 is selectively formed on the principal surface of silicon beam 4 and silicon substrate 1 as shown in FIG. 3. Because powerful tensile stress occurs in silicon nitride film 3, pad oxide film 2 is formed below silicon nitride film 3 to prevent damage to the silicon substrate resulting from this stress.

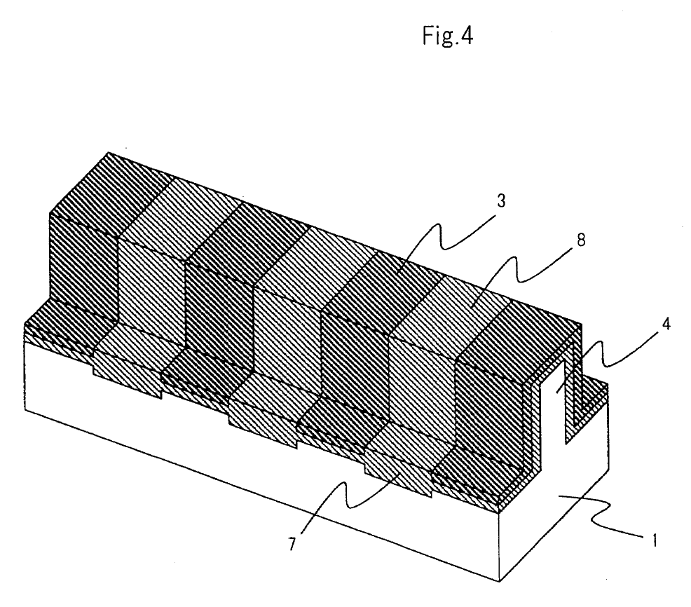

Next, as shown in FIG. 4, oxidation is carried out by a wet oxidation method at 1000° C. for twenty minutes to form a silicon oxide film having a thickness of 200 nm in portions that are not covered by silicon nitride film 3. An oxide film having greater film thickness than pad oxide film 2 is formed in portions of the surfaces of silicon beam 4 and silicon substrate 1 that are not covered by silicon nitride film 3. The oxide film having great film thickness that is formed on the surface of silicon substrate 1 is referred to as substrate field oxide film 7. In addition, the oxide film of great film thickness that is formed on the surface of silicon beam 4 is referred to as beam field oxide film 8. The crystal orientation of the side surfaces of silicon beam 4 differs from that of the substrate principal surface and top surface of silicon beam 4, and the oxidation rates therefore differ to some degree. As a result, the oxide film thicknesses of the side surfaces of silicon beam 4 and those of the substrate principal surface and top surface of silicon beam 4 also differ to some degree.

Explanation next regards the oxide film resulting from the thermal oxidation of silicon. Normally, when a thermal oxidation method is used to form a silicon oxide film having thickness X nm on a silicon substrate, a silicon oxide film having a film thickness of approximately (X/2) nm in the direction of depth from the principal surface of the silicon substrate is formed, and a silicon oxide film having a film thickness of approximately (X/2) nm is formed on the upper sides of the principal surface.

As a result, assuming that the thickness in the Y-axis direction of silicon beam 4 is 200 nm, when a silicon oxide film having a thickness of 200 nm is formed on the surface as described above, 100 nm of the side-walls on both sides are oxidized and all of silicon beam 4 is changed to a silicon oxide film. In other words, all of silicon beam 4 with the exception of portions that are covered by silicon nitride film 3 with pad oxide film 2 interposed is changed to a silicon oxide film.

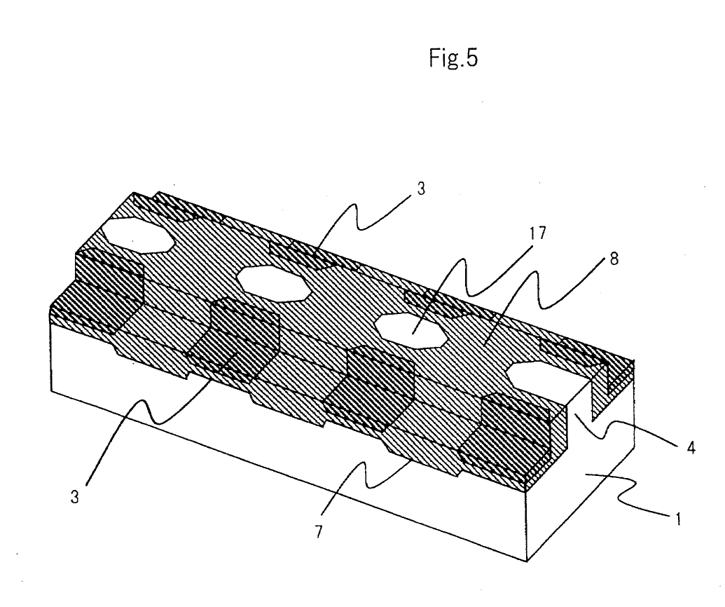

When the upper surface of the construction shown in FIG. 4 is leveled to a predetermined depth, areas other than portions that are covered by silicon nitride film 3 with pad oxide film 2 interposed all become silicon oxide film as shown in FIG. 5, but silicon beam 4 remains in portions that are covered by silicon nitride film 3. A profile in the Y-axis direction of the remaining silicon beam 4 has the shape shown in FIG. 5 because oxidation advances into these areas from the periphery of areas covered by silicon nitride film 3 during the thermal oxidation process. As shown in FIG. 5, in the present embodiment, the remaining silicon portions are formed intermittently. In the following explanation, the remaining silicon portions are referred to as pillar-shaped active regions 17.

As an example of the method of leveling the upper surface of the construction shown in FIG. 4, one method involves first forming an insulating film by CVD (Chemical Vapor Deposition) on the substrate surface, polishing the surface to a predetermined depth by a CMP (Chemical-Mechanical Polishing) method, and then removing the insulating film that was formed.

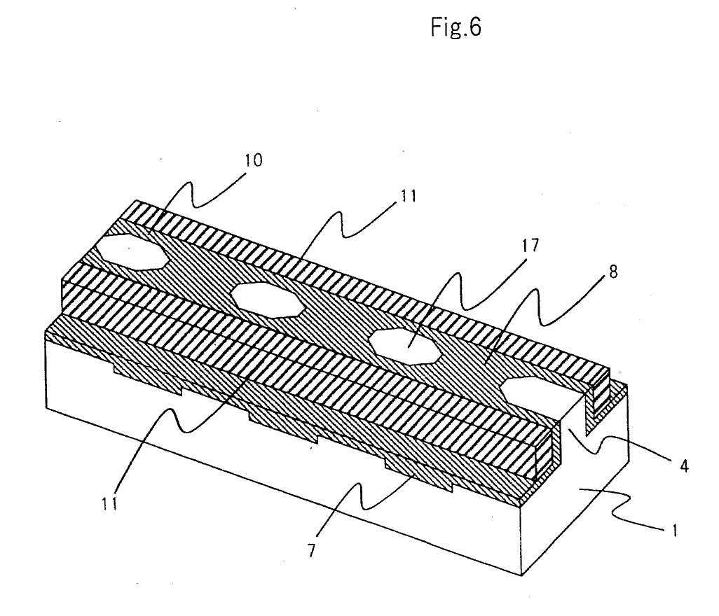

Silicon nitride film 3 is then removed by processing in hot phosphoric acid at 180° C. for 45 minutes, and pad oxide film 2 is removed. Next, gate oxide film 10 is formed to a film thickness of 5 nm on the side-walls of pillar-shaped active region 17 as shown in FIG. 6 by subjecting the substrate to dry oxidation at 900° C. for 10 minutes.

A polycrystalline silicon film is next formed on the substrate surface by a film formation method such as LPCVD (Low-Pressure CVD) method. A conductive impurity is then added to the polycrystalline silicon film such that the concentration of a conductive impurity such as phosphorus, arsenic, or boron is at least 10²⁰/cm³ to give the film conductivity. The method of adding the conductive impurity may be a combination of an ion implantation method and heat treatment, or may be a thermal diffusion method. The entire surface of the polycrystalline silicon film in which the conductive impurity has been diffused is then subjected to anisotropic dry etching such that polycrystalline silicon remains on the side-walls of silicon beam 4 as shown in FIG. 6. The polycrystalline silicon that remains on the side-walls becomes gate electrodes 11.

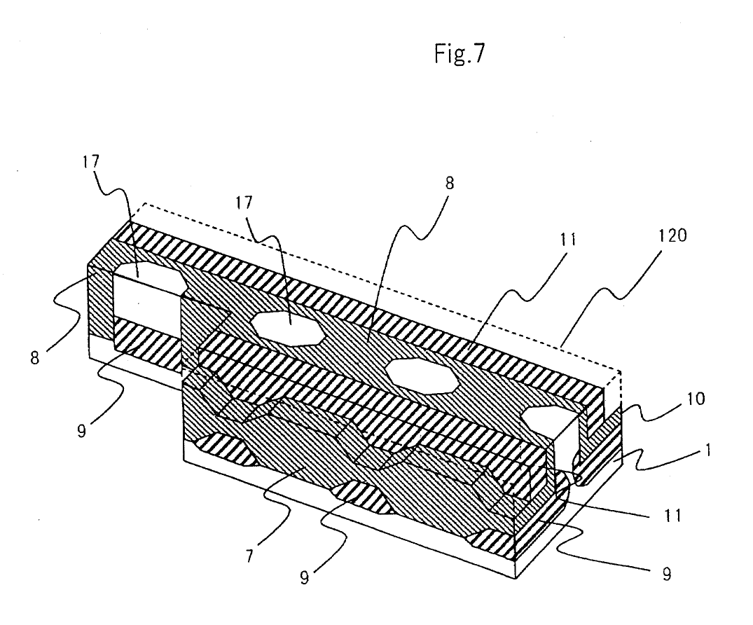

Arsenic is implanted into the construction shown in FIG. 6 with an acceleration energy of 30 keV and a dosage of 5×10¹⁵/cm² and instantaneous annealing (rapid thermal annealing) is carried out for ten seconds at 900° C. to form lower diffusion layers 9 in the vicinity of the principal surface of the substrate and form upper diffusion layers 14 (see FIG. 1) on the uppermost portion of pillar-shaped active region 17 as shown in FIG. 7. Thermal oxidation is then implemented to increase the film thickness of substrate field oxide film 7 and thus effect element isolation of the FETs. FIG. 7 shows the state in which interlayer dielectric film 120 is formed and the surface has been leveled by a CMP process for a construction to be used for observations that will be described hereinbelow.

After the above-described processes, a polycrystalline silicon film into which a conductive impurity is added is further formed over the entire substrate surface and a photo-etching method is carried out to pattern the polycrystalline silicon film, thereby forming electrodes 16 (see FIG. 1) that are connected to upper diffusion layers 14. Interlayer dielectric film 12, of which a CVD SiO₂ film is representative, is then formed over the entire substrate surface to complete fabrication of the basic construction of the present embodiment shown in FIG. 1.

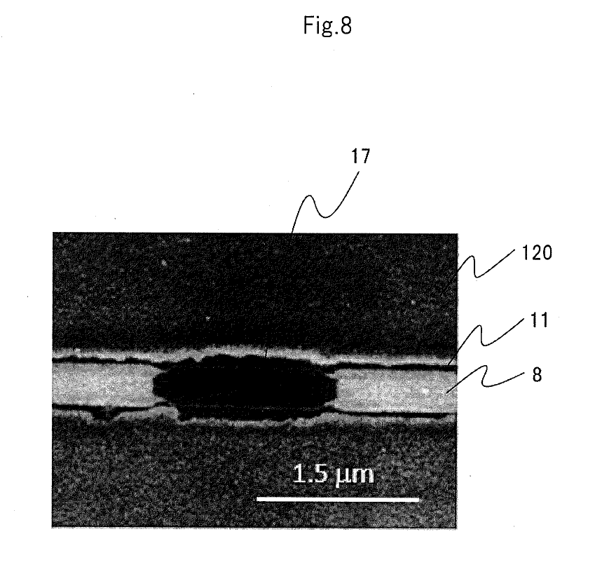

A construction of the present embodiment that was actually test-manufactured is next described. FIG. 8 is a photograph taken by a scanning electron microscope (SEM) from directly above the construction that was prepared for observations shown in FIG. 7.

As shown in FIG. 8, gate electrodes 11 are formed on the side-walls of pillar-shaped active region 17. In addition, field oxide film 8 is formed on sites of the silicon beam other than the pillar-shaped active regions 17. From the photograph of FIG. 8, it can be seen that if a plurality of pillar-shaped active regions 17 are intermittently provided, the elements are isolated by field oxide film 8.

In this test manufacture, the width of silicon beam 4 was made approximately 400 nm. As a result, the thickness of beam field oxide film 8 should be approximately twice this thickness, i.e., 800 nm. However, beam field oxide film 8 becomes thinner than 800 nm due to various processes such as etching processes and cleaning processes in the fabrication process, and in the example of the configuration shown in FIG. 8, beam field oxide film 8 has been thinned to a thickness of substantially the same order as the thickness of pillar-shaped active region 17. As a result, the thickness of remaining beam field oxide film 8 can be set to a desired value by integrating the series of fabrication processes for FET fabrication to control the amount of etching of beam field oxide film 8.

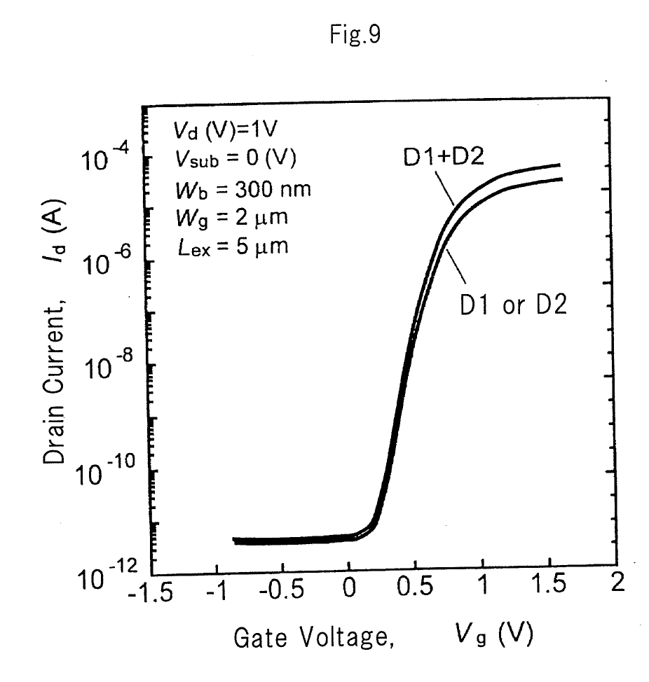

Explanation next regards electrical characteristics of the test-manufactured field effect transistor of the construction shown in FIG. 1. FIG. 9 is a graph showing the measurement results of the drain current and gate voltage characteristic (Id Vgcharacteristic) of the field effect transistor of the present embodiment.

In the FET that was measured, the thickness (Wb) of pillar-shaped active region 17 was 300 nm, the width (Wg) of pillar-shaped active region 17 was 2 μm, and the effective channel length (Lex) was 5 μm. The width (Wg) of pillar-shaped active region 17 corresponds to the gate width of the FET. In the measurements, the drain voltage (Vd) was 1 V, and the substrate voltage (Vsub) which is the voltage applied to silicon substrate 1, was 0 V.

Each of the pair of lower diffusion layers 9 provided on the lower portion of pillar-shaped active region 17 that is formed on a portion of silicon beam 4 was taken as the source electrode of a separate FET, and upper diffusion layer 14 served as the common drain electrode, and the drain current that flows between the source electrode and drain electrode of each FET was measured while varying the gate voltage.

In the graph of FIG. 9, D1 indicates the change of the drain current of one FET of the pair of FETs, and D2 indicates the change of the drain current of the other FET. As shown in FIG. 9, D1 and D2 are substantially identical and therefore appear to overlap. When the two FETs that are connected in parallel are placed in operation simultaneously, the change of the drain current is the sum of D1 and D2, and the drain current during ON operation is substantially doubled compared to D1 or D2.

In the construction of the present embodiment, upper diffusion layer 14 is shared by two FETs, but if upper diffusion layer 14 is electrically separated between right and left when viewing silicon beam 4 in the X-axis direction of FIG. 1, two FETs can be provided by one pillar-shaped active region 17. The details of an embodiment of this construction will be described later.

### Second Embodiment

Typically, when electrodes 16 are formed on a minute area such as upper diffusion layer 14 described in the first embodiment, the pattern of upper diffusion layer 14 and the pattern of electrodes 16 must be positioned precisely. As a result, high precision is required for mechanical positioning in the photolithographic process for forming the mask that is necessary for patterning of electrodes 16. The present embodiment enables a relaxation of this required precision.

The construction of the present embodiment is first described.

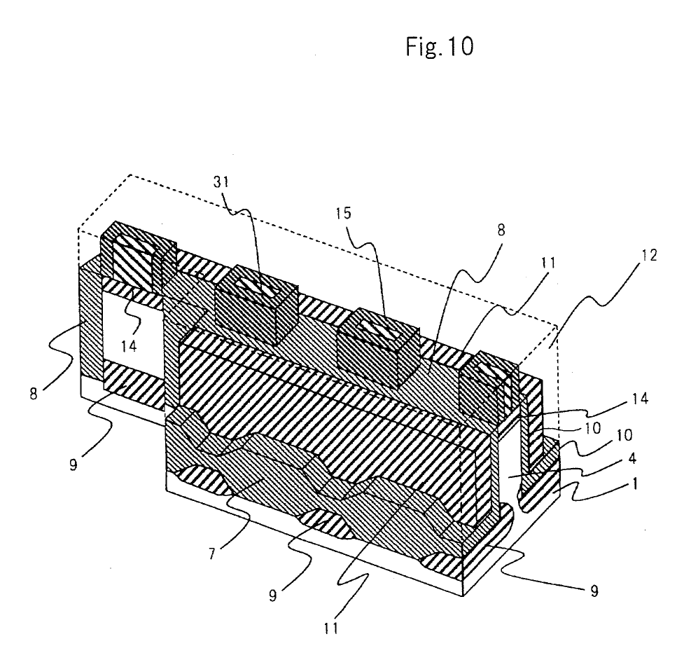

FIG. 10 is an outer perspective view showing an example of the configuration of the field effect transistor of the present embodiment. Constituent elements that are identical to the first embodiment are given the same reference numbers, and detailed explanation of these elements is here omitted.

As shown in FIG. 10, the site of each electrode 16 shown in FIG. 1 in the first embodiment is of a configuration that includes electrode 31 and side-wall film 15 that covers the side surfaces of electrode 31 in the present embodiment.

A first insulating film having openings that expose the upper surface of upper diffusion layer 14 is formed on the construction shown in FIG. 7, and after forming a second insulating film on at least the bottom surfaces and inner walls of these openings, the second insulating film is subjected to anisotropic etching to form side-wall film 15 on the inside walls of the openings. In this way, openings in which the cross section that is parallel to the XY plane is smaller than the original opening are formed by self-alignment. Electrodes 31 are formed by filling these openings with a conductive material.

Compared to the case of electrodes 16, the cross section of the openings of electrodes 31 is reduced by the film thickness of side-wall film 15. As a result, even in the event of a shift of the positioning of the opening pattern, all of the lower surfaces of electrodes 31 will contact the upper surfaces of upper diffusion layer 14 if the shift is within the range of the film thickness of side-wall film 15. In the case of the above-described construction, positioning accuracy between patterns can be relaxed to the extent of the film thickness of side-wall film 15.

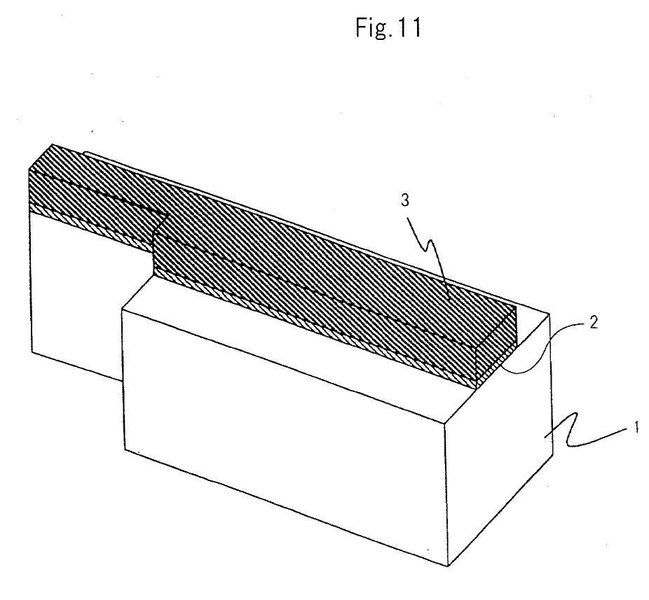

Although electrodes for connecting to narrow pillar-shaped silicon are difficult to form on the silicon in this way, a method of fabricating a field effect transistor of the present embodiment in which electrodes are formed by self-alignment on the silicon pillars is next described in detail. FIGS. 11 to 22 are outer perspective views for explaining the method of fabricating the field effect transistor of the present embodiment.

As shown in FIG. 11, the surface of silicon substrate 1 is subjected to thermal oxidation to form pad oxide film 2 to a film thickness of 10 nm. Silicon nitride film 3 is formed on pad oxide film 2 to a film thickness of 150 nm by a CVD method. A resist mask is formed by a normal lithography step such that silicon nitride film 3 is left in linear form, unnecessary silicon nitride film 3 being removed by etching. Pad oxide film 2 is etched by the same resist mask.

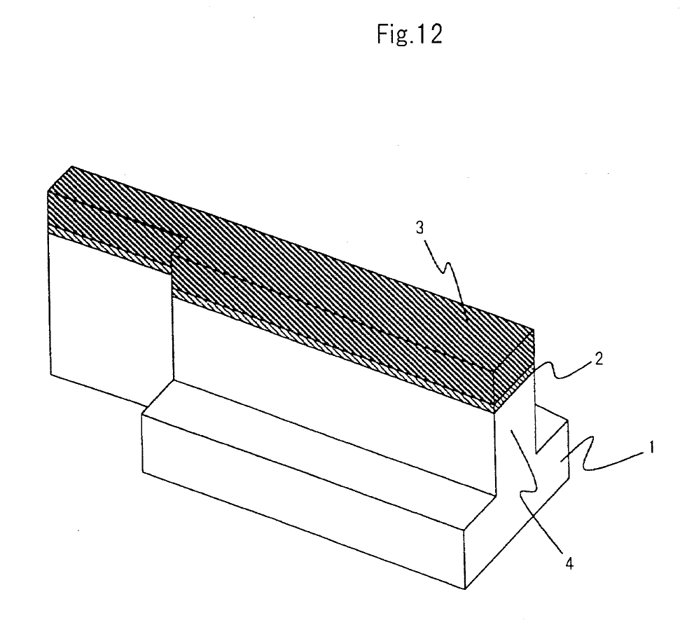

Next, as shown in FIG. 12, silicon substrate 1 is etched using silicon nitride film 3 as a mask to form silicon beam 4 with a height of 100 nm and a width of 40 nm.

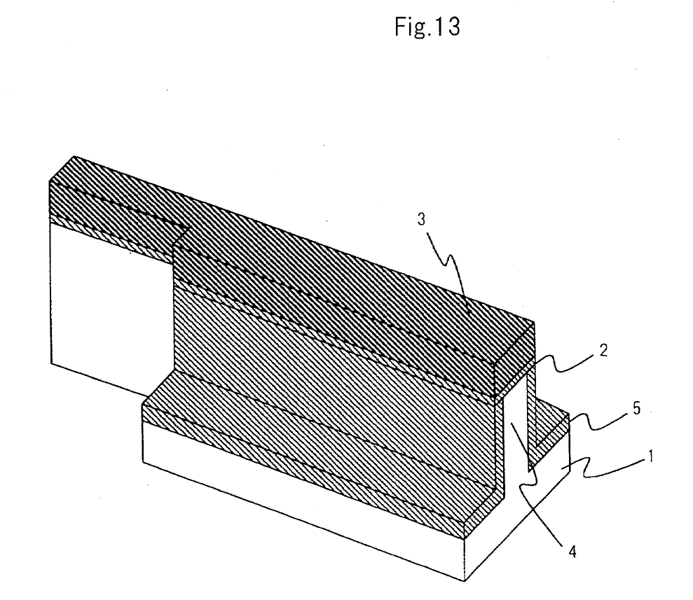

The exposed silicon portions are subjected to radical thermal oxidation to form silicon oxide film 5 to a film thickness of 5 nm on the surface, as shown in FIG. 13. Although not shown in the figure, at this time, silicon oxide film is formed to a film thickness of 5 nm on the surface of exposed silicon nitride film 3 as well. Although not shown in the figure, this silicon oxide film is indicated in the text by reference number 5a to distinguish from other silicon oxide film.

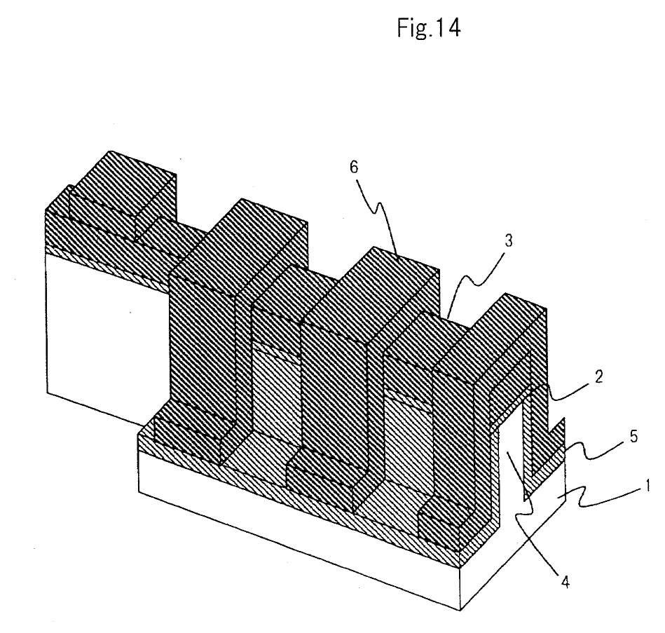

Next, as shown in FIG. 14, silicon nitride film 6 is formed to a film thickness of 10 nm over the entire surface of the construction shown in FIG. 13, and silicon oxide film (not shown in the figure) is then formed to a film thickness of 20 nm. Although not shown in the figure, this silicon oxide film is indicated in the text by reference number 32 to distinguish from other silicon oxide film. As shown in FIG. 14, a resist mask is formed by a normal lithographic step such that silicon nitride film 6 is left in linear form in the Y-axis direction, and unnecessary silicon oxide film 32 and silicon nitride film 6 are etched. When silicon nitride film 6 is etched, the surface of initial silicon nitride film 3 is protected by silicon oxide film 5a at this time and is therefore not etched. Here, the processing pitch of silicon nitride film 6 is 120 nm, the line width is 70 nm, and the spacing is 50 nm.

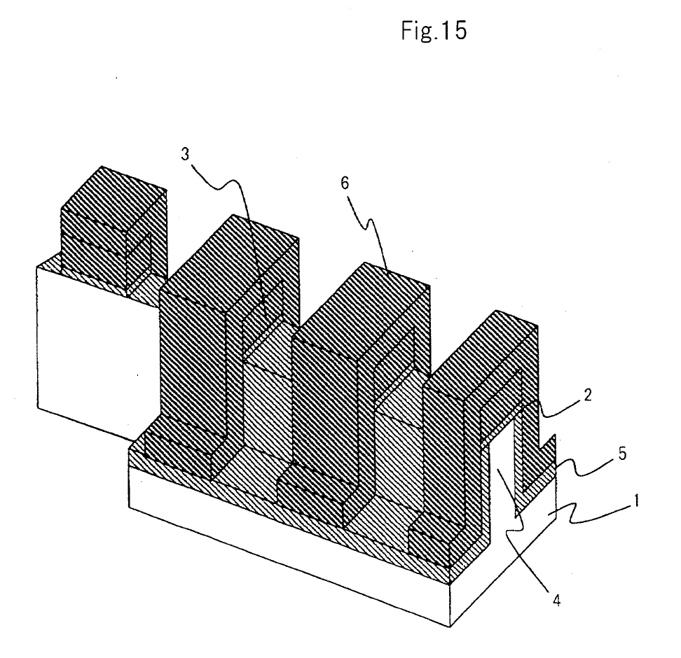

Next, as shown in FIG. 15, silicon oxide film 5a having a film thickness 5 nm that is formed on the surface of the portions of silicon nitride film 3 that are not covered by silicon nitride film 6 is etched. At this time, silicon oxide film 32 on silicon nitride film 6 has a film thickness on the order of 13 nm. The upper surface of silicon nitride film 3 is exposed between the patterns of silicon nitride film 6. Silicon nitride film 3 that is exposed on the upper surface is next etched using silicon oxide film 32 on silicon nitride film 6 as a mask.

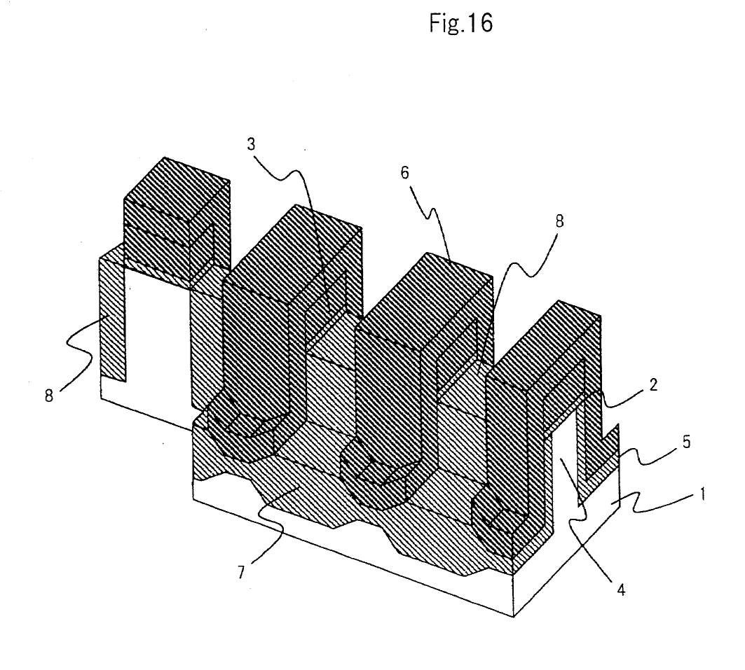

Sites in which silicon nitride film 3 and silicon nitride film 6 are not formed are next subjected to thermal oxidation to form substrate field oxide film 7 and beam field oxide film 8 as shown in FIG. 16. The oxidation conditions are set such that the film thickness is 30 nm for substrate field oxide film 7 that was formed in portions other than silicon beam 4. In this thermal oxidation, oxidation proceeds not only on the upper surfaces of silicon beam 4 but also from the side surfaces of silicon beam 4, and further, as shown by substrate field oxide film 7 of FIG. 16, oxidation also proceeds from the lower portion of silicon beam 4. As a result, beam field oxide film 8 that is formed at points of silicon beam 4 has an oxide film volume of nearly twice the volume of oxidized silicon beam 4, and the film thickness in the direction of width of silicon beam 4 reaches 50 nm. As a result, points of silicon beam 4 that are not covered by silicon nitride film 6 are entirely oxidized. This result is obtained because converting the doubling of volume to a dimensional increase in each direction of silicon beam 4 results in the cube root of integer 2, or a multiple of approximately 1.25.

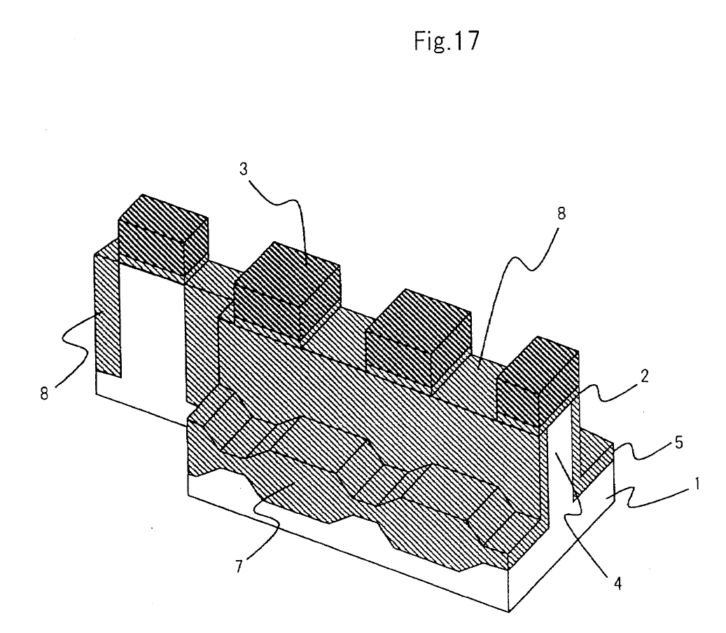

Silicon nitride film 6 is next removed as shown in FIG. 17. At this time, silicon nitride film 3 is also subjected to isotropic etching, but a pattern such as shown in FIG. 17 is left.

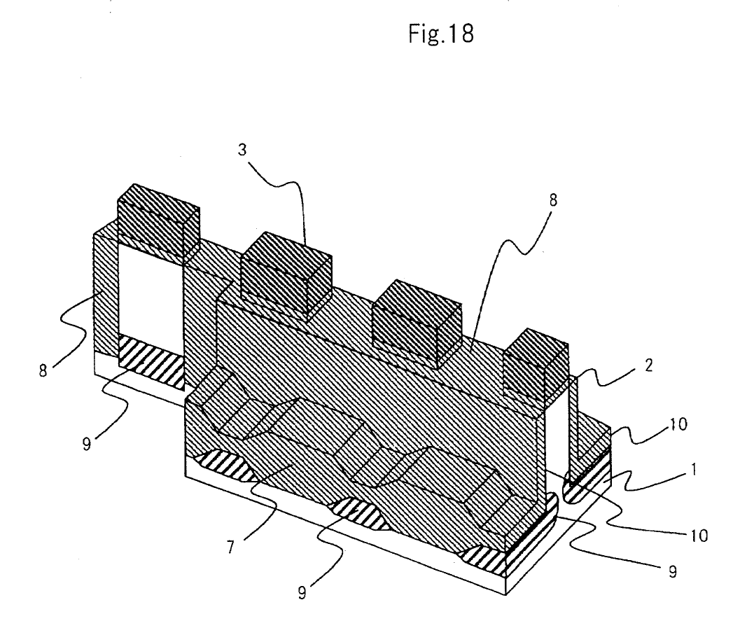

In the construction shown in FIG. 17, ion implantation of arsenic is carried out with an acceleration energy of 10 KeV and a dosage of 5×10¹⁴/cm², following which a heat treatment is carried out at 900° for 10 seconds to form lower diffusion layers 9 as shown in FIG. 18. These lower diffusion layers 9 extend in a Y-axis direction that is perpendicular with respect to the longitudinal direction of silicon beam 4. Silicon oxide film 5 shown in FIG. 17 is then removed and gate oxide film 10 is formed to a film thickness of 5 nm as shown in FIG. 18. If the FET of the present embodiment is applied as a cell transistor of a memory cell, lower diffusion layers 9 can be used as bit lines.

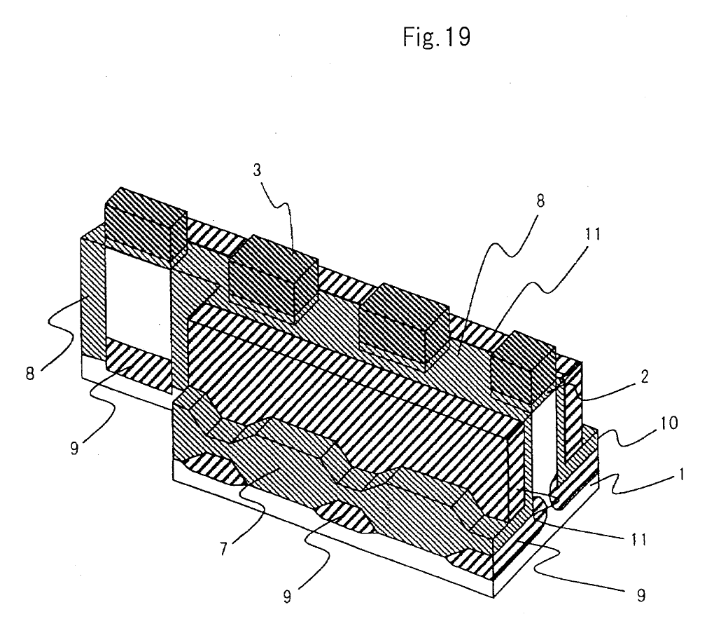

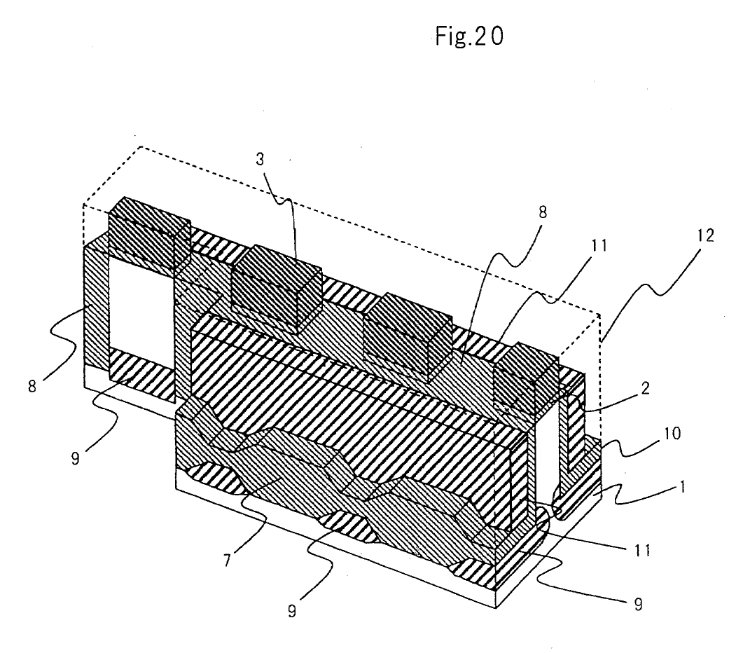

Next, after depositing a polycrystalline silicon film in which phosphorus has been introduced to 4×10²⁰/cm³ on the construction shown in FIG. 18, this polycrystalline silicon film is etched back to form gate electrodes 11 in side-wall form on the silicon beam side-walls as shown in FIG. 19. These gate electrodes 11 extend along the longitudinal direction of silicon beam 4. Interlayer dielectric film 12 (shown by the broken lines in FIG. 20) is then deposited as shown in FIG. 20, interlayer dielectric film 12 is subjected to CMP to level the surface and expose the upper surface of silicon nitride film 3. When lower diffusion layers 9 are used as bit lines as previously described, gate electrodes 11 can be used as word lines that are orthogonal to the bit lines.

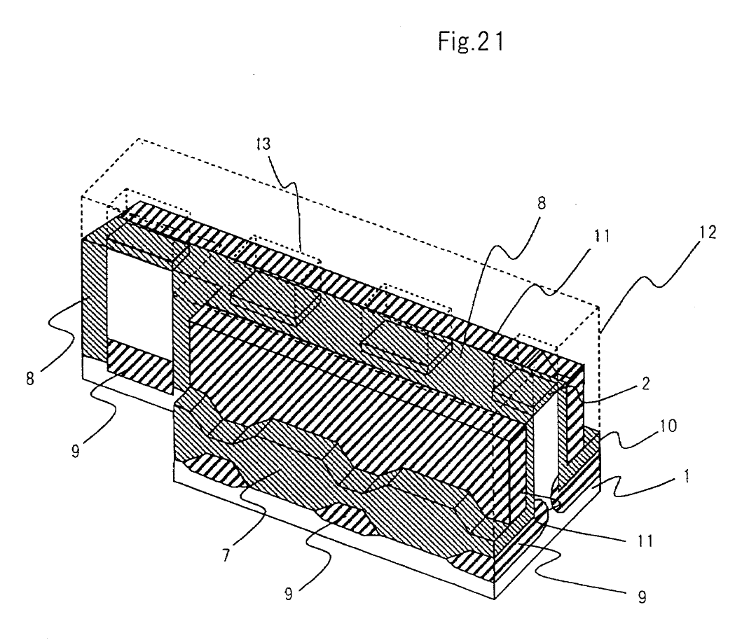

Silicon nitride film 3 shown in FIG. 20 is next removed, and openings 13 are formed in interlayer dielectric film 12 as shown in FIG. 21. Conductive impurity is then introduced into the upper portion of silicon beam 4 by way of openings 13 to form upper diffusion layers 14. The formation conditions and formation method of these upper diffusion layers 14 are similar to those for lower diffusion layers 9 and a detailed explanation is therefore here omitted. In addition, conductive impurity is implanted into the silicon portion that is interposed between lower diffusion layers 9 and upper diffusion layers 14 and the channel concentration thus controlled. Control of this channel concentration enables free setting of the threshold value voltage.

Silicon nitride film 3 shown in FIG. 20 is next removed, and openings 13 are formed in interlayer dielectric film 12 as shown in FIG. 21. Conductive impurity is then introduced into the upper portion of silicon beam 4 by way of openings 13 to form upper diffusion layers 14. The formation conditions and formation method of these upper diffusion layers 14 are similar to those for lower diffusion layers 9 and a detailed explanation is therefore here omitted. In addition, conductive impurity is implanted into the silicon portion that is interposed between lower diffusion layers 9 and upper diffusion layers 14 and the channel concentration thus controlled. Control of this channel concentration enables free setting of the threshold value voltage.

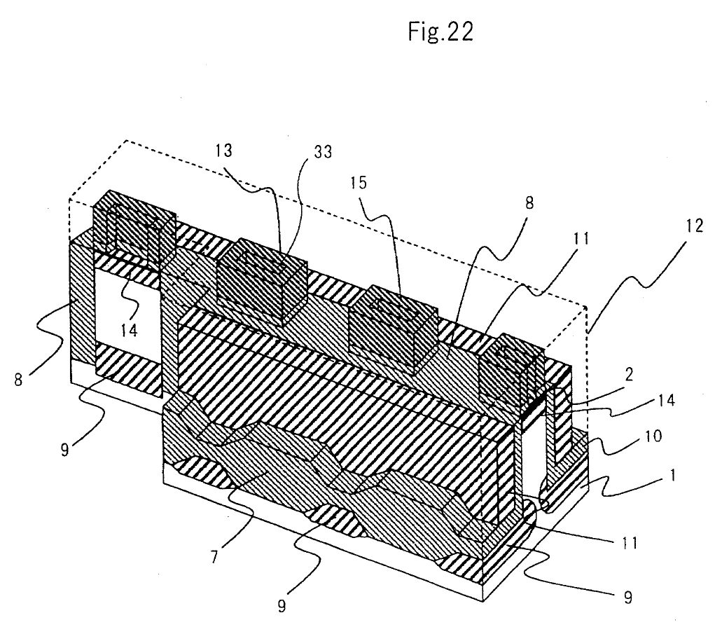

A silicon nitride film is next deposited to a film thickness of 5 nm over the construction shown in FIG. 21. At this time, a silicon nitride film is formed on the bottom surfaces and in the side-walls in openings 13 of interlayer dielectric film 12. Next, by subjecting the silicon nitride film to etch-back, not only is side-wall film 15 having a film thickness of 5 nm formed on the side-walls of openings 13 as shown in FIG. 22, but silicon nitride film that was formed on interlayer dielectric film 12 is also removed. Openings 33 having open areas that are smaller than openings 13 are formed in openings 13.

Pad oxide film 2 at sites of the upper surface that were exposed in openings 33 is subjected to etching to expose the upper surface of upper diffusion layers 14. Openings 33 are then filled with a conductive material to form electrodes 31, whereby fabrication of the construction shown in FIG. 10 is realized.

In addition, continuous processing in the same device is possible by merely modifying etching conditions such as the etching gas of the anisotropic etching for forming side-wall film 15 and the subsequent etching of pad oxide film 2.

### Third Embodiment

If attention is focused on a single pillar-shaped active region 17 in the first and second embodiments, two lower diffusion layers 9 are formed below pillar-shaped active region 17 and a single upper diffusion layer 14 is formed above. If upper diffusion layer 14 serves as the source electrode of the FETs, two FETs with a common source are formed. If upper diffusion layer 14 serves as the drain electrode of the FETs, two FETs with a common drain are formed.

In either case, because either the source electrodes or the drain electrodes of two FETs are shared, the FETs cannot operate as independent transistors. The present embodiment is of a configuration provided with not only one pair of electrically isolated lower diffusion layers 9 corresponding to one pillar-shaped active region 17 but also with one pair of electrically isolated upper diffusion layers 14. In the following explanation, the construction of the FET of the present embodiment is described in detail while describing its method of fabrication.

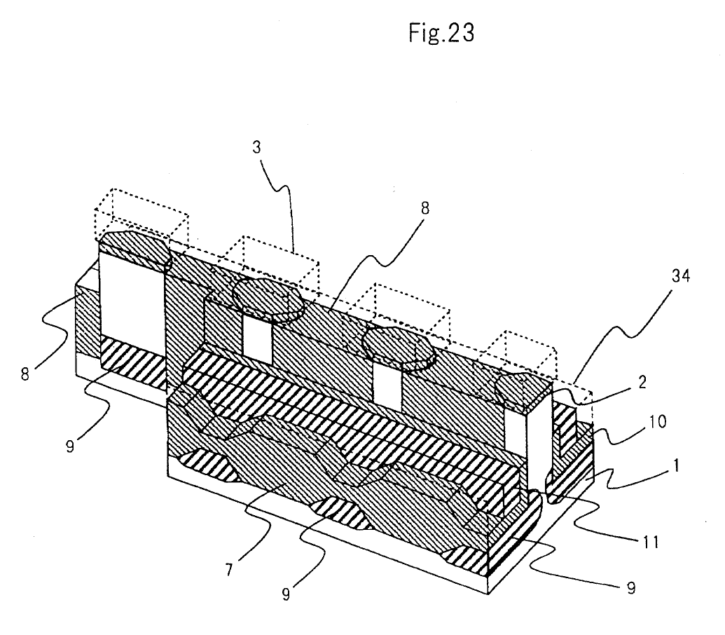

FIGS. 23 to 25 are outer perspective views for explaining the method of fabricating the field effect transistor of the present embodiment.

In the formation of the gate electrodes that is midway in the processing of the construction from FIG. 18 to FIG. 19 described in the second embodiment, gate electrode 11 shown in FIG. 19 is further subjected to etching, whereby the height from the substrate surface to the upper surface of gate electrode 11 is lower than the construction shown in FIG. 19. In the example shown in FIG. 23, the height of the upper surface of gate electrode 11 is approximately half the height of silicon beam 4. Next, as shown in FIG. 23, a portion of gate oxide film 10 that covers the side surfaces of pillar-shaped active regions 17 is subjected to etching. At this time, the side surfaces of pad oxide film 2 that were covered by silicon nitride film 3 are also etched, whereby pad oxide film 2 takes on the shape shown in FIG. 23.

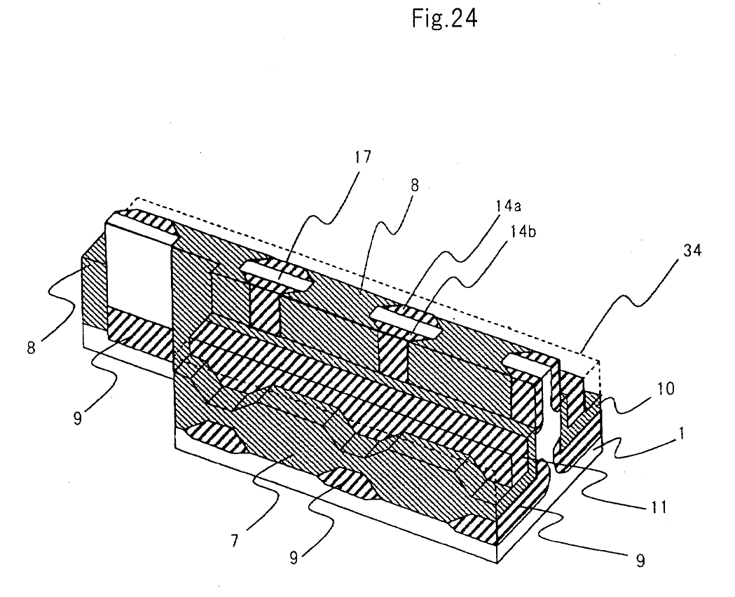

Conductive impurity is then diffused into pillar-shaped active regions 17 from exposed points of the side-walls of pillar-shaped active regions 17 by means of an ion implantation method or gas diffusion method to form upper diffusion layers 14a and 14b as shown in FIG. 24. Upper diffusion layers 14a and 14b are provided on opposite sides with the active layers interposed, and are electrically isolated into two regions. In FIG. 24, pad oxide film 2 and silicon nitride film 3 that were shown in FIG. 23 are omitted from the figure in the interest of showing the inner construction. In addition, interlayer dielectric film 34 may be formed on the substrate surface as shown in FIG. 23 and FIG. 24 to prevent the reduction of substrate field oxide film 7 during the process of etching silicon oxide film.

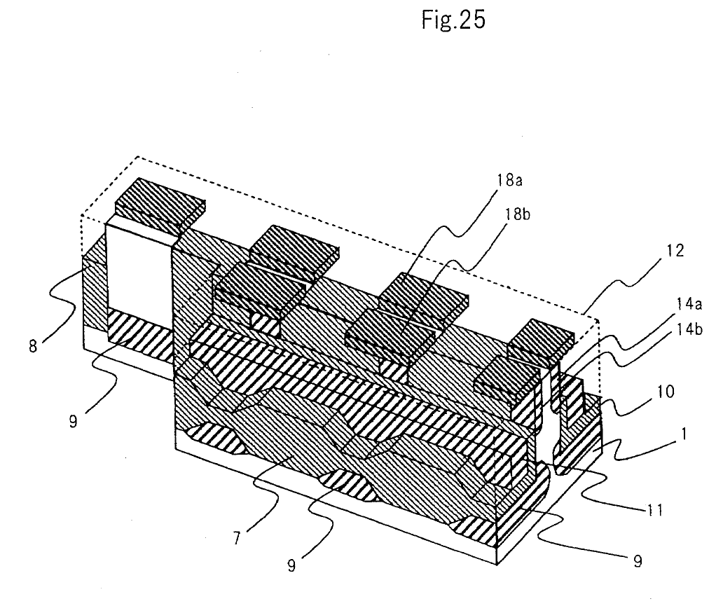

After upper diffusion layers 14a and 14b have been formed, interlayer dielectric film 12 is formed over the entire surface of the substrate, following which CMP is implemented to both level the upper surface of interlayer dielectric film 12 and expose the upper surfaces of upper diffusion layers 14a and 14b. Epitaxial layers are next formed by self-alignment on the upper surfaces of pillar-shaped active regions 17 by means of a selective epitaxial growth method, and these epitaxial layers are patterned by a photo-etching method to form electrode lead lines 18a and 18b that are composed of silicon as shown in FIG. 25. As shown in FIG. 25, electrode lead line 18a is connected to upper diffusion layer 14a and electrode lead line 18b is connected to upper diffusion layer 14b. To give electrode lead lines 18a and 18b conductivity, a conductive impurity such as phosphorus or arsenic is added by means of an ion implantation method or a gas diffusion method. The addition of a conductive impurity may be carried out either before or after the patterning of the epitaxial layer.

As shown in FIG. 25, a pair of FETs is formed corresponding to one pillar-shaped active region 17. Each of this pair of FETs is separately provided with a source electrode and a drain electrode and can therefore operate independently. If the typical processing dimension is F, the theoretical area of a pillar-shaped transistor is 4F², but the inclusion of two transistors in the construction of the present embodiment results in an area of 2F². As a result, twice the density can be achieved while using the same processing dimensions.

The gate length of the FETs depends on the height of gate electrode 11, as shown in FIG. 24. Although explanation regarded a case in which the height of gate electrode 11 was made approximately half the height of silicon beam 4 in the present embodiment, the present invention is not limited to this form, and the height of gate electrode 11 can be determined to match the gate length that is set. The longer the gate length, the higher the position of the upper surface of gate electrode 11.

In addition, electrode lead lines 18a and 18b may be employ a metal such as aluminum or copper as the material and may be formed by a photo-etching method.

### Fourth Embodiment

In the first to third embodiments, the silicon of the regions of silicon beam 4 that are interposed between pillar-shaped active regions 17 was all converted to oxide film, and each of pillar-shaped active regions 17 that were formed adjacently were electrically insulated and isolated. The present embodiment is of a configuration in which, rather than converting all of the regions interposed between pillar-shaped active regions 17 to oxide film, semiconductor regions are left, whereby adjacent pillar-shaped active regions 17 are connected by semiconductor regions.

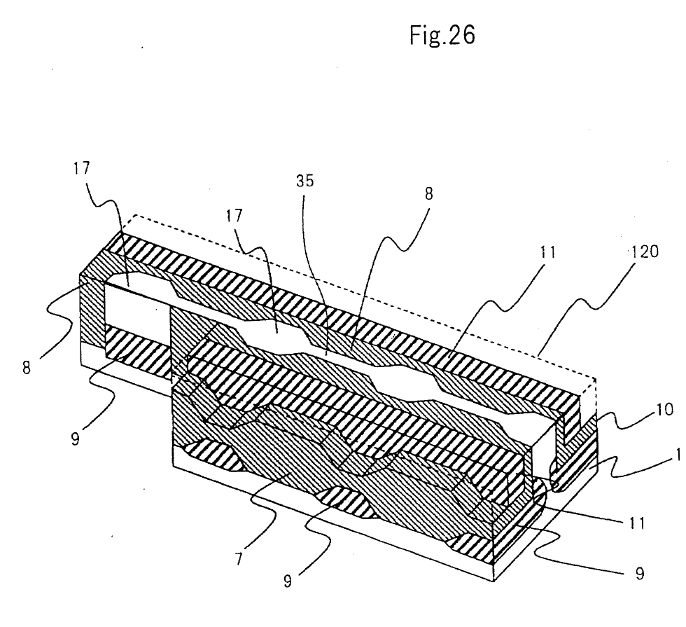

FIG. 26 is an outer perspective view showing an example of the configuration of a field effect transistor of the present embodiment. FIG. 26 shows characteristic portions of the present embodiment taking the construction shown in FIG. 7 as a base.

As shown in FIG. 26, adjacent pillar-shaped active regions 17 are connected by semiconductor regions 35. If there is sufficient thickness in the film thickness of beam field oxide film 8 as in a normal planar FET, leak current that flows between adjacent pillar-shaped active regions and that is detrimental to the operation of FET can be prevented.

According to the present embodiment, a plurality of pillar-shaped active regions 17 are formed linked together, whereby the substrate potential can be easily applied simultaneously to this plurality of pillar-shaped active regions 17. In addition, the connection of pillar-shaped active regions 17 to silicon substrate 1 over a large area hinders the influence of induced noise from the outside. The construction of the present embodiment may also be applied to the first to third embodiments.

Although explanation regarded constructions in which gate electrodes 11 were provided on both side-walls of silicon beam 4 in the first to fourth embodiments, gate electrode 11 may also be provided on only one side-wall of silicon beam 4.

### Fifth Embodiment

Although embodiments of field effect transistors as separate entities were described in the first to fourth embodiments, the present embodiment describes cases of application of the field effect transistors that were described in these embodiments in cell transistors of various memory devices (semiconductor memory devices).

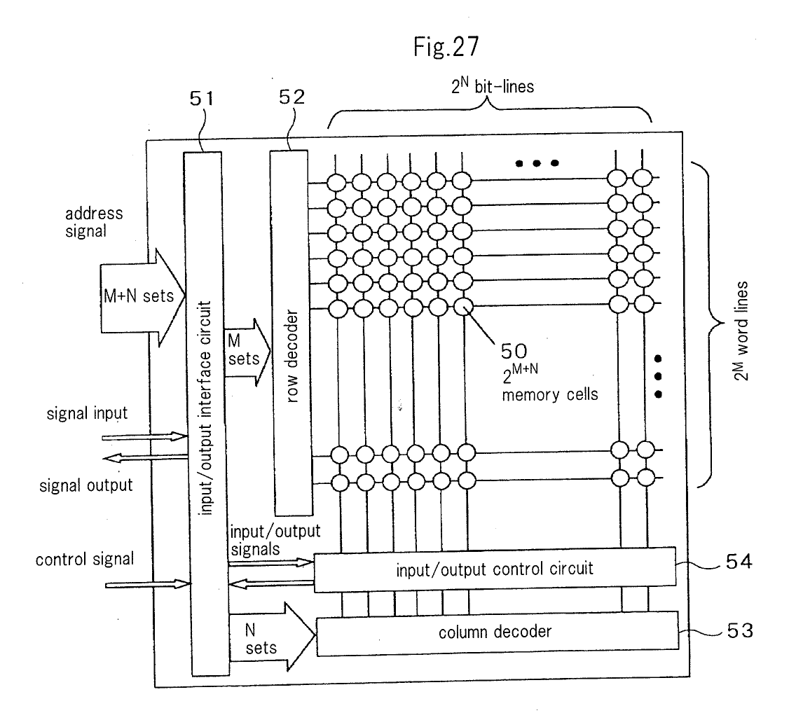

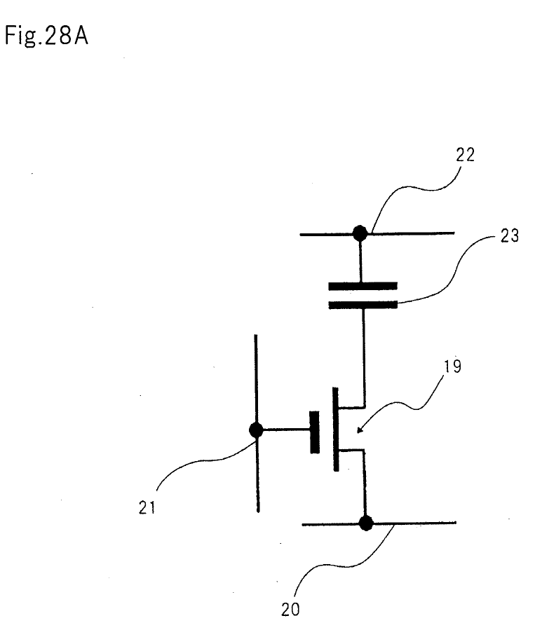

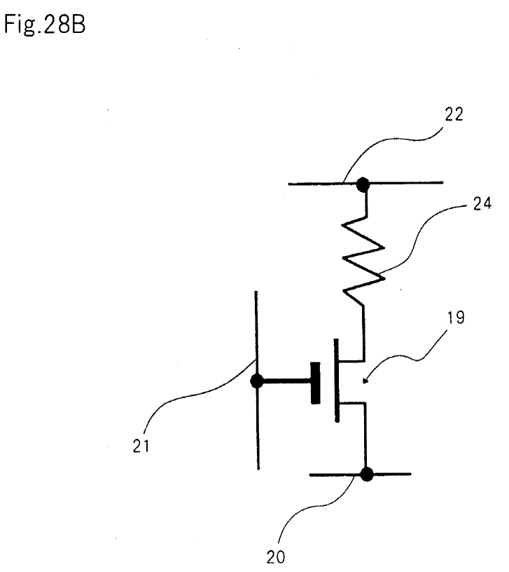

FIG. 27 is a block diagram showing an example of the configuration of a semiconductor memory device and shows a typical two-dimensional memory matrix array. FIGS. 28A and 28B show examples of circuits when the field effect transistor of the present invention is used in a cell transistor of a memory cell.

As shown in FIG. 27, the semiconductor memory device includes: a plurality of memory cells 50, input/output interface circuit 51, row decoder 52, column decoder 53, and input/output control circuit 54. FIG. 27 shows a case in which 2^{M}×2^{N} memory cells 50 are provided in a memory cell array. Each of memory cell A shown in FIG. 28A and memory cell B shown in FIG. 28B is an example of memory cell 50.

Input/output interface circuit 51 shown in FIG. 27, upon receiving as input an address signal in which a row and column are designated, reports the row information to row decoder 52 and reports the column information to column decoder 53. Row decoder 52 applies a predetermined voltage to word-line 21 of the designated row, and column decoder 53 applies a predetermined voltage to bit-line 20 of the designated column. Memory cell 50 that is located in the row and column that were designated by the address signal thus assumes a readable or writable state.

Input/output interface circuit 51 further, when a control signal that instructs writing is received as input and there is an input signal that contains information of the object of writing, transfers the input signal to input/output control circuit 54 and writes the information of the input signal to memory cell 50 that was designated by the address signal. On the other hand, upon receiving as input a control signal that instructs reading, input/output interface circuit 51 transfers the control signal to input/output control circuit 54, reads the information that is stored in memory cell 50 that was designated by the address signal to input/output control circuit 54, and thus supplies the information.

Memory cell A shown in FIG. 28A includes FET 19 of the present invention and capacitor memory element 23. Word-line 21 is connected to the gate electrode of FET 19, and bit-line 20 is connected to the drain electrode. One electrode of capacitor memory element 23 is connected to the source electrode of FET 19, and the other electrode of capacitor memory element 23 is connected to plate electrode 22.

Memory cell B shown in FIG. 28B is of a configuration in which capacitor memory element 23 of memory cell A shown in FIG. 28A is replaced by resistor memory element 24. Memory cell B is of the same configuration as memory cell A with the exception of resistor memory element 24, and a detailed description regarding memory cell B is therefore here omitted.

If a normal dielectric film is used in capacitor memory element 23, memory cell A becomes DRAM that stores memory as charge. If an element that polarizes upon application of a strong field is used in capacitor memory element 23, memory cell A becomes ferroelectric memory (FeRAM).

If tunneling magneto resistance (TMR) element is used in resistor memory element 24, memory cell B becomes magnetic random access memory (MRAM). If crystalline phase-change element of chalcogenide film is used in resistor memory element 24, memory cell B becomes a phase-change memory (PCM). If a strongly-correlated electron-system material that exhibits the colossal electro-resistance (CER) effect is used in resistor memory element 24, memory cell B becomes resistive random access memory (ReRAM). If a solid electrolytic film is used for resistor memory element 24, memory cell B becomes a solid electrolyte memory. In any case, information that is stored is in memory cell B is stored as a change in resistance.

In the present embodiment, a case was described in which plate electrode 22 is connected to one of the terminals of the two memory elements, i.e., capacitor memory element 23 and resistor memory element 24, but a form in which plate electrode 22 is caused to operate as a bit-line can also be considered, and of the two terminals of the memory element, the name of the connection destination of the terminal that is not connected to a cell transistor is not limited to plate electrode. The gist of the present invention is not altered by the name. The present embodiment can be realized regardless of the form of operation as a memory element.

In the field effect transistor of the present embodiment described hereinabove, the active region of a field effect transistor is formed on a projecting part on a substrate surface that extends in a fixed direction parallel to the surface and is therefore stronger in a direction parallel to the substrate surface than the pillar-shaped vertical field effect transistor that was disclosed in Patent Document 1. As a result, collapse or deformation of the active region during a cleaning step is prevented.

In addition, according to the field effect transistor of the present embodiment, although element-isolation regions and active regions are alternately formed, these components are all formed as a unit in a fixed direction, whereby the gate electrodes of a plurality of transistors can be formed by self-alignment on beam-shaped silicon side-walls. The field effect transistor of Patent Document 1 is of a construction in which the gate electrodes remain as side-walls in the vicinity of pillars, but photo-etching is required to form a pattern for making connections between pillars for the gate electrodes provided for each pillar, and further, mask alignment is required between patterns for this purpose, whereby micro-arrangement becomes problematic.

In the construction disclosed in Patent Document 1, after the formation of silicon pillars, cladding with an insulating film of great thickness is required to bury inter-pillar silicon for forming element-isolation regions, and the processing is therefore difficult. In the fabrication method of a field effect transistor of the present embodiment, a silicon beam that extends in a fixed direction is converted intermittently to oxide film, whereby intermittent element-isolation regions are formed. As a result, a plurality of electrically isolated silicon pillars that extend in a fixed direction can be formed. By making the silicon pillars the active regions of transistors, a transistor group can be formed at high density and with high mechanical strength. Still further, in the construction of the present embodiment, two field effect transistors can be formed for one pillar-shaped active region to achieve an even higher degree of density.

It is apparent that the present invention is not limited to the above embodiments, but may be modified and changed without departing from the scope and spirit of the invention.

What is claimed is:

1. A field effect transistor comprising:
an active region provided on a projecting part on a surface of a semiconductor substrate, said projecting part extending in a fixed direction parallel to said surface; and
a gate electrode that is provided on a sidewall of said projecting part along said fixed direction with a gate insulating film interposed.

2. The field effect transistor according to claim 1, wherein two said gate electrodes are provided on opposite sides of said projecting part with said gate insulating film provided on two side-walls of said projecting part interposed.

3. The field effect transistor according to claim 1, wherein a plurality of said active regions and regions for effecting element isolation in said fixed direction for each of said plurality of active regions are provided on said projecting part.

4. The field effect transistor according to claim 2, wherein a plurality of said active regions and regions for effecting element isolation in said fixed direction for each of said plurality of active regions are provided on said projecting part.

5. The field effect transistor according to claim 1, wherein a diffusion layer that serves as a source electrode or a drain electrode is provided on an upper surface of said active region.

6. The field effect transistor according to claim 2, wherein a diffusion layer that serves as a source electrode or a drain electrode is provided on an upper surface of said active region.

7. The field effect transistor according to claim 6, wherein said diffusion layer is electrically separated into two regions corresponding to said two gate electrodes.

8. A memory cell comprising:
a field effect transistor according to claim 1, said field effect transistor serving as a cell transistor; and
a memory element connected to said field effect transistor.

9. A fabrication method of a field effect transistor comprising:
on a surface of a semiconductor substrate, forming by said semiconductor substrate a projecting part that extends in a fixed direction that is parallel to said surface;
selectively oxidizing said projecting part to form active regions at remaining sites;
forming gate insulating films on side-walls of said projecting part;
forming gate electrodes that contact said gate insulation films along said fixed direction; and
forming diffusion layers for source electrodes and drain electrodes on an upper portion of said active region and in the vicinity of said surface of said semiconductor substrate.

10. The fabrication method of a field effect transistor according to claim 9, further comprising:
forming a first insulating film in which first openings are located over said diffusion layer provided on said upper portion of said active region;
forming a second insulating film in at least said first openings;
subjecting said second insulating film to anisotropic etching to expose portions on said upper surface of said diffusion layer and to form, in said first openings, second openings having side-walls realized from said second insulating film; and
filling said second openings with conductive material.
